(19) United States
(12) Patent Application Publication
(10) Pub. No.: US 2025/0107285 A1
(43) Pub. Date: Mar. 27, 2025

(54) LIGHT EMITTING DEVICE AND INSULATING ANTI-REFLECTIVE LAYER USED FOR LIGHT EMITTING DEVICE

(71) Applicant: TOYODA GOSEI CO., LTD., Kiyosu-shi (JP)

(72) Inventors: Hiroaki MAKINO, Kiyosu-shi (JP); Hideki OMOYA, Kiyosu-shi (JP); Shinichi MATSUI, Kiyosu-shi (JP); Koichi MIZUTANI, Kiyosu-shi (JP)

(21) Appl. No.: 18/796,795

(22) Filed: Aug. 7, 2024

(30) Foreign Application Priority Data
Sep. 25, 2023 (JP) 2023-159366

(51) Int. Cl. H01L 33/44; H01L 33/32; H01L 33/42

(52) U.S. Cl. CPC H10H 20/84; H10H 20/825; H10H 20/833

(57) ABSTRACT

The present disclosure provides a face-up type ultraviolet light emitting device capable of improving the light extraction efficiency. The face-up type ultraviolet light emitting device includes an n-type layer made of n-type group III nitride semiconductor, an active layer formed on the n-type layer and made of group III nitride semiconductor, a p-type layer formed on the active layer 22 and made of p-type group III nitride semiconductor, a p-side electrode formed on one part on the p-type layer, an insulating anti-reflective layer formed on other part on the p-type layer, made of a material having insulating properties, and preventing reflection of ultraviolet light with an emission wavelength.

### CROSS-REFERENCE

This application claims priority to Japanese patent application no. 2023-159366 filed on Sep. 25, 2023, the contents of which are fully incorporated herein by reference.

### BACKGROUND OF THE INVENTION

### Technical Field

The present disclosure relates to a light emitting device and an insulating anti-reflective layer used for the light emitting device.

### Background Art

The wavelength of ultraviolet light emitted from a solid-state light emitting device made of group III nitride semiconductor corresponds to a wavelength band in a range of approximately 200 nm to 400 nm. Particularly, UVC (ultraviolet C, wavelength of 100 nm to 280 nm) is known to efficiently sterilize or disinfect, and the demand is increasing for a group III nitride semiconductor light emitting device that emits ultraviolet light with an emission wavelength of UVC. The ultraviolet light emitting device has a structure in which an AlN layer is formed on a sapphire substrate, and an n-type layer made of AlGaN, an active layer, and a p-type layer are deposited on the AlN layer.

JP-A-2022-19963, JP-A-2019-176016, and JP-A-2011-155084 disclose an ultraviolet light emitting device having a face-up (FU) type structure. The ultraviolet light emitting device disclosed in JP-A-2022-19963 and JP-A-2019-176016, includes p-contact electrode formed on a p-type semiconductor layer and made of a transparent electrode such as ITO, and a p-electrode formed on the p contact electrode and having a structure of Ti, Rh, and Ti deposited.

The ultraviolet light emitting device disclosed in JP-A-2011-155084 includes a transparent electrode formed on a p-type semiconductor layer, and a protective layer formed on the transparent electrode and made of a transparent insulating material, and protecting the transparent electrode at ultraviolet light with an emission wavelength. The transparent electrode has a transparent metal layer made of a metal material selected from a group consisting of Na, K, Cs, and Rb and having a light absorption coefficient of 5×10⁴ cm⁻¹ or less for ultraviolet light with an emission wavelength. The insulating material of the protective layer is MgF₂.

JP-A-2014-22609 discloses a face-up type structure of a semiconductor light emitting device that emits a blue light (wavelength of 440 nm to 460 nm) instead of ultraviolet light. The blue light emitting device shown in FIG. 12 of JP-A-2014-22609 includes a transparent electrode film formed on a p-type semiconductor layer and made of ZnO or ITO, and a conductive multilayered anti-reflective layer formed on the transparent electrode film. The conductive multilayered anti-reflective layer is formed by alternately depositing two types of transparent electrode layers having different refractive indices, for example, InₓGa₁₋ₓO layer and Nb₂O₅ layer. The refractive index of InGaO₃ is approximately 1.6, and the refractive index of Nb₂O₅ is approximately 2.4.

### SUMMARY OF THE INVENTION

The light extraction efficiency of the ultraviolet light emitting device is lower than the light extraction efficiency of the blue light emitting device. Particularly, in the face-up type ultraviolet light emitting device disclosed in JP-A-2022-19963, JP-A-2019-176016, and JP-A-2011-155084, ultraviolet light is absorbed by an electrode, causing a reduction in light extraction efficiency.

One aspect of the present disclosure has been made in view of such a background, and an object thereof is to provide a face-up type ultraviolet light emitting device capable of improving the light extraction efficiency. The other aspect of the present disclosure is applied to a face-up type ultraviolet light emitting device and an object thereof is to provide an insulating anti-reflective layer for improving the light extraction efficiency.

One aspect of the present disclosure is a face-up type ultraviolet light emitting device including:
an n-type layer made of n-type group III nitride semiconductor;
an active layer formed on the n-type layer and made of group III nitride semiconductor;
a p-type layer formed on the active layer and made of p-type group III nitride semiconductor;
a p-side electrode formed on one part on the p-type layer; and
an insulating anti-reflective layer formed on other part on the p-type layer, made of a material having insulating properties, and preventing reflection of ultraviolet light with an emission wavelength.

As used herein, unless otherwise specified, the term “on” broadly encompasses both “directly on” and “indirectly on”.

The other aspect of the present disclosure is an insulating anti-reflective layer used for a face-up type ultraviolet light emitting device, formed on a p-type layer, containing at least one selected from a group consisting of Hf oxide, Zr oxide, Si oxide, Al oxide, and Mg fluoride, and preventing reflection of ultraviolet light with an emission wavelength.

According to one aspect of the present disclosure, a p-side electrode is formed in one region on the p-type layer, and an insulating anti-reflective layer is formed in other region on the p-type layer. The insulating anti-reflective layer has a function to prevent reflection of ultraviolet light with an emission wavelength. Therefore, the light extraction efficiency of ultraviolet light can be increased in a region where the insulating anti-reflective layer is disposed.

According to the other aspect of the present disclosure, the insulating anti-reflective layer contains at least one selected from a group consisting of Hf oxide, Zr oxide, Si oxide, Al oxide, and Mg fluoride. This can achieve excellent anti-reflection effect of ultraviolet light with an emission wavelength.

The above aspects of the present disclosure can provide a face-up type ultraviolet light emitting device capable of improving the light extraction efficiency. Moreover, the above aspects of the present disclosure can provide an anti-reflective layer applied to the face-up type ultraviolet light emitting device for improving the extraction efficiency.

### BRIEF DESCRIPTION OF THE DRAWINGS

FIG. 1 is a cross-sectional view illustrating light emitting device according to an embodiment;

FIG. 2 is a plan view viewed from the top of the light emitting device shown in FIG. 1;

FIG. 3 shows the result of Experiment 1, which is a graph showing a relationship between thickness of p-side transparent electrode and transmittance of ultraviolet light with a wavelength of 280 nm; and

FIG. 4 shows the result of Experiment 2, which is a graph showing a relationship between emission wavelength and transmittance.

### DETAILED DESCRIPTION OF PREFERRED EMBODIMENTS

As described above, a face-up type ultraviolet light emitting device includes an n-type layer made of n-type group III nitride semiconductor, an active layer formed on the n-type layer and made of group III nitride semiconductor, a p-type layer formed on the active layer and made of p-type group III nitride semiconductor, a p-side electrode formed on one part on the top of the p-type layer, and an insulating anti-reflective layer formed on other part on the top of the p-type layer and made of a material having insulating properties, and preventing reflection of ultraviolet light with an emission wavelength.

The light emitting device further may include a p-side transparent electrode formed on and in contact with the p-type layer, and transmitting ultraviolet light with an emission wavelength. The p-side electrode is preferably formed on one part on the p-side transparent electrode, and the insulating anti-reflective layer is preferably formed on other part on the p-side transparent electrode. By forming the p-side transparent electrode on the p-type layer, the contact resistance with the p-type layer can be reduced, thereby improving the emission efficiency.

The refractive index of the insulating anti-reflective layer is preferably set between the refractive index of the p-side transparent electrode and the refractive index of air. This allows the improvement of the light extraction efficiency.

The insulating anti-reflective layer preferably has a multilayer structure formed by depositing materials having different refractive indices. This allows that reflections are mutually weakened by the interference of light. As a result, the light extraction efficiency can be improved.

The insulating anti-reflective layer preferably includes at least one selected from a group consisting of Hf oxide, Zr oxide, Si oxide, Al oxide, and Mg fluoride. Thereby, the insulating anti-reflective layer can be formed so as to have a desired function.

The p-side transparent electrode is preferably formed thinner than the thickness of the insulating anti-reflective layer. Thereby, the antireflection function can be enhanced in the insulating anti-reflective layer while improving the transmittance of ultraviolet light in the p-side transparent electrode. As a result, the light extraction efficiency can be improved.

The thickness of the p-side transparent electrode is preferably 40 nm or less. Thus, the transmittance of ultraviolet light can be increased in the p-side transparent electrode. Moreover, the thickness of the insulating anti-reflective layer is preferably 1 nm to 300 nm. The p-type layer is preferably made of GaN or AlGaN.

### Embodiment

### 1. Configuration of Light Emitting Device 1

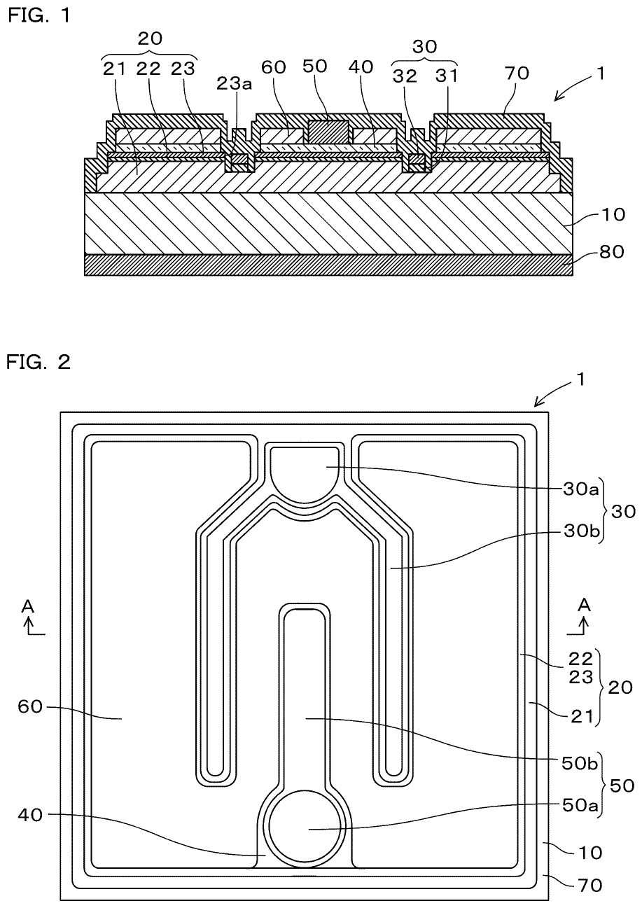

A configuration of a light emitting device 1 according to the present embodiment will be described with reference to FIGS. 1 and 2. FIG. 1 is a cross-sectional view perpendicular to the main surface of a substrate. FIG. 2 is a view illustrating a planar pattern of the light emitting device 1 according to the present embodiment. The cross section of FIG. 1 corresponds to a cross section taken along line A-A in FIG. 2.

As shown in FIG. 1, the light emitting device 1 according to the present embodiment includes a substrate 10, a semiconductor layer 20, an n-side electrode 30, a p-side transparent electrode 40, a p-side electrode 50, an insulating anti-reflective layer 60, a protective layer 70, and a reflective layer 80. The light emitting device 1 is a face-up type, that is, has a structure of extracting light from the surface on the p-side electrode 50 side (top surface in FIG. 1). The light emitting device 1 is a light emitting device that emits ultraviolet light having an emission wavelength of 100 nm to 400 nm, particularly, deep ultraviolet light having an emission wavelength of 100 nm to 280 nm (UVC band).

The substrate 10 is a substrate made of, for example, sapphire. The orientation of the main surface of the substrate 10 is, for example, a-plane or c-plane. The substrate 10 may have an off-angle of 0.1° to 2° in the m-axis direction. The substrate 10 may be made of any material other than sapphire as long as it has a high transmittance of ultraviolet light with an emission wavelength and group III nitride semiconductor can be crystal grown thereon. For example, the substrate 10 may be an AlN substrate or an AlN template substrate having an AlN layer on the sapphire substrate.

The semiconductor layer 20 is formed by crystal growth on the main surface of the substrate 10. The semiconductor layer 20 contains group III nitride semiconductor. The semiconductor layer 20 includes at least an n-type layer 21, an active layer 22, and a p-type layer 23. The semiconductor layer 20 is formed by depositing the n-type layer 21, the active layer 22, and the p-type layer 23 in this order on the substrate 10.

The n-type layer 21 is formed on the substrate 10. The n-type layer 21 is made of n-type group III nitride semiconductor. The n-type layer 21 is made of, for example, n-AlGaN. The Al composition (molar ratio of Al to the total of group III metals) is, for example, 60% to 90% in the n-type layer 21. The n-type impurity in the n-type layer 21 is Si, and the Si concentration is, for example, 1×10¹⁸ cm⁻³ to 5×10¹⁹ cm⁻³. The thickness of the n-type layer 21 is, for example, 0.5 μm to 5 μm. The C concentration of the n-type layer 21 is 1×10¹⁵ cm⁻³ to 1×10¹⁹ cm⁻³. The n-type layer 21 may have a plurality of layers. For example, the n-type layer 21 may be a super lattice layer in which AlGaN having different Al compositions are alternately deposited. A base layer made of AlN may be formed between the substrate 10 and the n-type layer 21. Any material other than Si may be used as the n-type impurity.

The active layer 22 is formed on the n-type layer 21. The active layer 22 is made of group III nitride semiconductor. The active layer 22 has a single quantum well (SQW) structure in which a barrier layer, a well layer, and a barrier layer are deposited in this order on the n-type layer 21. The active layer 22 may have a multiple quantum well (MQW) structure. In that case, the number of repetitions in MQW structure is, for example, 2 to 10.

The well layer is made of AlGaN, and the Al composition is set according to a desired emission wavelength. The Si concentration of the well layer is, for example, 1×10¹⁸ cm⁻³ or less, and the well layer may be undoped. The thickness of the well layer is, for example, 0.5 nm to 5 nm.

The barrier layer is made of AlGaN having an Al composition higher than the Al composition of the well layer, and the Al composition is, for example, 50% to 100%. The Si concentration of the barrier layer is, for example, 2×10¹⁹ cm⁻³ or less, and the barrier layer may be undoped. The thickness of the barrier layer is, for example, 3 nm to 30 nm. The barrier layer may be made of AlGaInN having a band gap energy larger than the band gap energy of the well layer.

An electron hole blocking layer may be formed between the n-type layer 21 and the active layer 22. The electron hole blocking layer can suppress the electron holes injected from the p-side electrode 50 from passing through the active layer 22 and dispersing into the n-type layer 21. The electron hole blocking layer is made of AlGaN or AlN having an Al composition higher than the Al composition of the barrier layer of the active layer 22. The thickness of the electron hole blocking layer is, for example, one molecular layer to 2 nm. In the case of AlN, the thickness of one molecular layer is approximately 0.26 nm.

The p-type layer 23 is formed on the active layer 22. The p-type layer 23 is made of group III nitride semiconductor. The p-type layer 23 is also referred to as p-type contact layer because it is in contact with the electrode. The p-type layer 23 may be made of p-GaN doped with Mg, or p-AlGaN. When the p-type layer 23 is made of p-AlGaN, the Al composition is, for example, 50% or less, preferably, 30% or less.

When the p-type layer 23 is made of GaN, the thickness of the p-type layer 23 is preferably 1 nm to 50 nm. GaN may absorb ultraviolet light emitted from the active layer 22. However, the p-type layer 23 can transmit ultraviolet light by sufficiently reducing the thickness. Thereby, a significant reduction in the external quantum efficiency can be avoided. The thickness of the p-type layer 23 is preferably 1 nm to 10 nm. The Mg concentration of the p-type layer 23 is, for example, 1×10²⁰ cm⁻³ to 1×10²² cm⁻³.

The p-type layer 23 may have a plurality of layers having different Al compositions or Mg concentrations. When the p-type layer 23 has a plurality of layers, the top layer in contact with the p-side transparent electrode 40 is preferably made of p-GaN, or AlGaN having a low Al composition to reduce the contact resistance with the p-side transparent electrode 40. In this case, the Al composition of the AlGaN layer having a low Al composition is 50% or less, preferably 30% or less. When the p-type layer 23 is made of AlGaN having an Al composition of 50% or less, the thickness of the p-type layer 23 is preferably 20 nm or less. The p-type layer 23 can transmit ultraviolet light by sufficiently reducing the thickness.

In a region of the surface of the p-type layer 23, a trench 23a with a depth reaching the n-type layer 21 is formed. This trench 23a is provided to expose the n-type layer 21 and form an n-side electrode 30.

An electron blocking layer may be formed between the active layer 22 and the p-type layer 23. The electron blocking layer can suppress the electrons injected from the n-side electrode 30 from passing through the active layer 22 and dispersing into the p-type layer 23. The electron blocking layer is made of group III nitride semiconductor. The electron blocking layer is made of AlGaN or AlN having an Al composition higher than the Al composition of the barrier layer of the active layer 22. The electron blocking layer may be doped with p-type impurity such as Mg, or may be undoped. The thickness of the electron blocking layer is, for example, 1 nm to 20 nm.

A composition gradient layer may be formed between the electron blocking layer and the p-type layer 23. The composition gradient layer is made of group III nitride semiconductor. The composition gradient layer is a layer exhibiting p-type conduction obtained by polarization doping. That is, the composition gradient layer is a layer in which the Al composition varies in a thickness direction thereof, and the Al composition is set to decrease with distance from the electron blocking layer. The Al composition of the p-type layer 23 is set lower than the lowest Al composition of the composition gradient layer. In AlGaN having a high Al composition, the electron hole concentration was difficult to increase by doping with Mg. However, the electron hole concentration can be improved by polarization doping, thereby increasing the efficiency of electron hole injection into the active layer 22. The composition gradient layer is not doped with Mg in polarization doping, thereby improving the crystallinity.

The n-side electrode 30 is formed on and in contact with the n-type layer 21 exposed in the bottom of the trench 23a. Here, as shown in FIG. 2, in a plan view of the light emitting device 1, the n-side electrode 30 includes a wire bonding portion 30a and a wiring portion 30b. The wire bonding portion 30a is formed in a vicinity of the center of one side (upper side of FIG. 2) of the rectangular substrate 10. The wire bonding portion 30a is bonded with a wire (not illustrated). The wire bonding portion 30a is formed in any shape such as a bowl, a rectangle, and a circle.

The wiring portion 30b is extended from the wire bonding portion 30a. The width of the wiring portion 30b is smaller than the diameter of the wire bonding portion 30a. For example, the wiring portion 30b is extended along a side adjacent to the side of the substrate 10 on which the wire bonding portion 30a is formed. In the present embodiment, a plurality of (for example, two) wiring portions 30b is extended in a folk shape from the wire bonding portion 30a. However, only one wiring portion 30b may be extended from the wire bonding portion 30a.

As shown in FIG. 1, the n-side electrode 30 has a first n-side electrode 31 and a second n-side electrode 32 in a direction perpendicular to the main surface of the substrate 10. The first n-side electrode 31 is formed on and in contact with the n-type layer 21 exposed in the bottom of the trench 23a. The first n-side electrode 31 is formed of V/Al/Ti, Ti/Al, or V/Al. Here, A/B means a layered structure in which B was formed after A was formed. Hereinafter, the same shall apply in this specification. The thickness of the first n-side electrode 31 is 100 nm to 300 nm.

The second n-side electrode 32 is formed on and in contact with the first n-side electrode 31. The second n-side electrode 32 is formed of Ti/Ni/Au/Al or Ti/Pt/Au/Al. The thickness of the second n-side electrode 32 is 300 nm to 600 nm.

The p-side transparent electrode 40 is formed on and in contact with the p-type layer 23. The p-side transparent electrode 40 is formed entirely on a region except for the periphery of the substrate 10 and the trench 23a. The p-side transparent electrode 40 transmits ultraviolet light with an emission wavelength. The p-side transparent electrode 40 is formed of ITO, IZO, NiAu, Rh, Ru, Mg, and other materials. These materials can achieve good contact with the p-type layer 23. When the p-side transparent electrode 40 is made of ITO, the refractive index of the p-side transparent electrode 40 is 2 to 2.5.

The thickness of the p-side transparent electrode 40 is 40 nm or less, preferably 20 nm or less. By setting the thickness of the p-side transparent electrode 40 as described above, transmittance of ultraviolet light can be increased. Moreover, the thickness of the p-side transparent electrode 40 is 1 nm or more, preferably 3 nm or more. By setting the thickness of the p-side transparent electrode 40 as described above, the p-side transparent electrode 40 can achieve good contact with the p-type layer 23.

The p-side transparent electrode 40 preferably has a structure so that the transmittance of a predetermined ultraviolet light with an emission wavelength is 30% or more, preferably 50% or more. For example, the p-side transparent electrode 40 preferably has a structure so that the transmittance of ultraviolet light having a wavelength of 280 nm is 30% or more, preferably 50% or more. As described above, by setting the thickness of the p-side transparent electrode 40 to 40 nm or less, the transmittance of ultraviolet light having a wavelength of 280 nm can be 30% or more. By setting the thickness of the p-side transparent electrode 40 to 20 nm or less, the transmittance of ultraviolet light having a wavelength of 280 nm can be 50% or more.

The p-side electrode 50 is formed on and in contact with one part on the p-side transparent electrode 40. Therefore, the p-side electrode 50 is formed indirectly on one part of the p-type layer 23.

As shown in FIG. 2, in a plan view of the light emitting device 1, the p-side electrode 50 includes a wire bonding portion 50a and a wiring portion 50b. The wire bonding portion 50a is formed in a vicinity of the center of the side opposite to the wire bonding portion 30a of the n-side electrode 30 (lower side of FIG. 2) of four sides of the rectangular substrate 10. The wire bonding portion 50a is bonded with a wire (not illustrated). The wire bonding portion 50a is formed in any shape such as a circle, a rectangle, and a bowl.

The wiring portion 50b is extended from the wire bonding portion 50a. The width of the wiring portion 50b is smaller than the diameter of the wire bonding portion 50a. For example, the wiring portion 50b is extended along a side adjacent to the side of the substrate 10 on which the wire bonding portion 50a is formed. In the present embodiment, one wiring portion 50b is extended from the wire bonding portion 50a. This one wiring portion 50b is disposed between two wiring portions 30b of the n-side electrode 30. However, a plurality of wiring portions 50b of the p-side electrode 50 may be extended in a folk shape.

The p-side electrode 50 is formed of Ti/Ni/Au/Al or Ti/Pt/Au/Al. The thickness of the p-side electrode 50 is 300 nm to 600 nm. The p-side electrode 50 is formed thicker than the thickness of the p-side transparent electrode 40. The p-side electrode 50 can be formed simultaneously with the second n-side electrode 32.

The insulating anti-reflective layer 60 is formed on other part of the p-side transparent electrode 40. That is, the insulating anti-reflective layer 60 is formed in a region except for the p-side electrode 50 on the p-side transparent electrode 40. Particularly, the insulating anti-reflective layer 60 is formed entirely on a region except for the part in contact with the p-side electrode 50 of the top surface of the p-side transparent electrode. Therefore, in a plan view of the light emitting device 1, the area of the insulating anti-reflective layer 60 is larger than the area in contact with the p-side transparent electrode 40 of the p-side electrode 50.

The insulating anti-reflective layer 60 is made of a material having insulating properties, prevents reflection of ultraviolet light with an emission wavelength, and transmits the ultraviolet light with an emission wavelength. The refractive index of the insulating anti-reflective layer 60 is set between refractive index (n=2 to 2.5) of the p-side transparent electrode 40 and the refractive index (n=about 1) of air. For example, the refractive index of the insulating anti-reflective layer 60 is preferably set to 1.4 to 1.9.

The insulating anti-reflective layer 60 contains at least one selected from a group consisting of Hf oxide, Zr oxide, Si oxide, Al oxide, and Mg fluoride. The insulating anti-reflective layer 60 contains, for example, HfO₂, ZrO₂, SiO₂, Al₂O₃, or MgF₂.

The insulating anti-reflective layer 60 may have a single layer structure or a multilayer structure. In the case of a multilayer structure, the insulating anti-reflective layer 60 has a structure in which materials having different refractive indices are deposited, and the thickness of each layer is preferably set so that reflections are mutually weakened by the interference of light. The insulating anti-reflective layer 60 is, for example, a film formed by depositing layers having refractive indices of 1.5 to 2.0/1.0 to 1.5/1.5 to 2.0, or a structure formed by repeating these films 1 to 3 times.

The thickness of the insulating anti-reflective layer 60 is 1 nm to 300 nm. The insulating anti-reflective layer 60 is formed thicker than the thickness of the p-side transparent electrode 40. In other words, the p-side transparent electrode 40 is formed thinner than the thickness of the insulating anti-reflective layer 60. The insulating anti-reflective layer 60 has the same thickness as the thickness of the p-side electrode 50.

The protective layer 70 is formed so as to cover the top surface of the light emitting device 1. The protective layer 70 is made of an insulating material such as SiO₂ or SiN.

Specifically, the protective layer 70 covers the exposed surface of the n-type layer 21, the exposed surface of the p-type layer 23, the exposed surface of the wiring portion 30b of the n-side electrode 30, the exposed surface of the p-side transparent electrode 40, the exposed surface of the wiring portion 50b of the p-side electrode 50, and the exposed surface of the insulating anti-reflective layer 60. However, the protective layer 70 is not formed on the top surface of the wire bonding portion 30a of the n-side electrode 30, and the wire bonding portion 30a is exposed so as to be bonded with the wire (not illustrated). Similarly, the protective layer 70 is not formed on the top surface of the wire bonding portion 50a of the p-side electrode 50, and the wire bonding portion 50a is exposed so as to be bonded with the wire (not illustrated).

The reflective layer 80 is formed on the rear surface of the substrate 10 (bottom of FIG. 1, surface opposite to the light extracting surface). The reflective layer 80 reflects the ultraviolet light emitted from the active layer 22 in a light extraction direction. The reflective layer 80 may have a single layer structure or a multilayer structure. The reflective layer 80 has, for example, a first layer formed in contact with the rear surface of the substrate 10, and a second layer formed in contact with the rear surface of the first layer. The first layer is made of, for example, SiO₂ or SiN. The second layer includes a reflective film made of, for example, Al, Rh, Ru, Mg, Al, or Ti/Ni/Au, and a layer formed on the rear surface of the reflective film and adhered to a metal paste. The reflective film of the second layer may be made of a material other than metal. The reflective layer 80 may be Distributed Bragg Reflector (DBR).

### 2. Experiments

### Experiment 1

In Experiment 1, using a sample 1 in which ITO corresponding to the p-side transparent electrode 40 was formed on the main surface of the sapphire substrate, the transmittance of the ultraviolet light having a wavelength of 280 nm was measured. Five types of samples 1 having different ITO thickness of 16 nm, 18 nm, 32 nm, 42 nm, and 105 nm were prepared.

The transmittance was 56%, 54%, 42%, 36%, and 12% for the ITO thickness of 16 nm, 18 nm, 32 nm, 42 nm, and 105 nm, respectively.

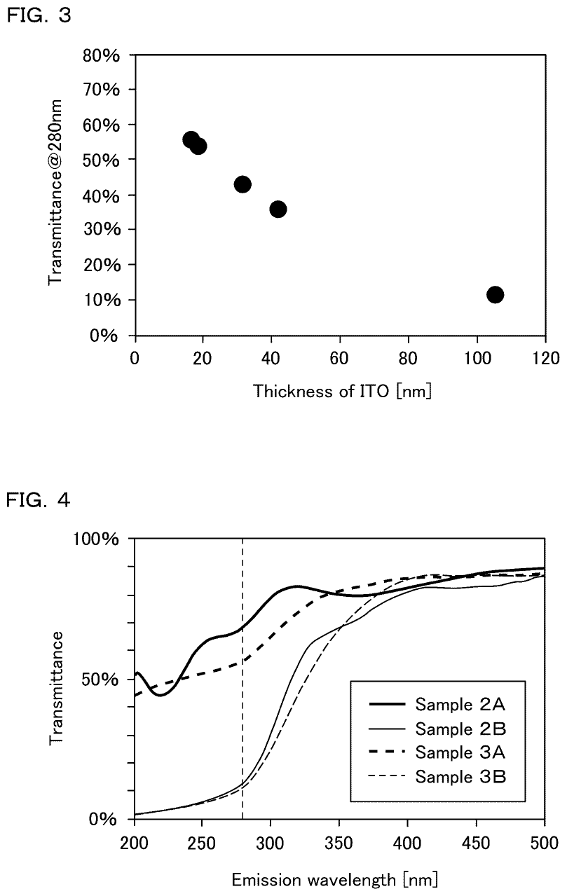

As shown in FIG. 3, from the results of Experiment 1, when the thickness of ITO is 40 nm or less, ITO can have a transmittance of 35% or more. Moreover, when the thickness of ITO is 20 nm or less, ITO can have a transmittance of 50% or more.

### Experiment 2

Next, in Experiment 2, using samples 2A and 2B in which ITO corresponding to the p-side transparent electrode 40 was formed on the main surface of the sapphire substrate, and further a layer corresponding to the insulating anti-reflective layer 60 was formed on the ITO, a relationship between the emission wavelength and the transmittance was measured. In the sample 2A, the thickness of ITO was 16 nm, and in the sample 2B, the thickness of ITO was 100 nm. In the samples 2A and 2B, the layer corresponding to the insulating anti-reflective layer 60 was a layer formed by depositing films having refractive indices of 1.5 to 2.0/1.0 to 1.5/1.5 to 2.0, and the thickness of the layer corresponding to the insulating anti-reflective layer 60 was 250 nm.

As Comparative Example, using samples 3A and 3B in which ITO corresponding to the p-side transparent electrode 40 was formed on the main surface of the sapphire substrate, a relationship between the emission wavelength and the transmittance was measured. In the samples 3A and 3B, a layer corresponding to the insulating anti-reflective layer 60 was not formed. In the sample 3A, the thickness of ITO was 16 nm, and in the sample 3B, the thickness of ITO was 100 nm.

As shown in FIG. 4, from the results of Experiment 2, at the wavelength of 280 nm, the transmittance was 68.8% in the sample 2A, the transmittance was 13.1% in the sample 2B, the transmittance was 56.8% in the sample 3A, and the transmittance was 11.5% in the sample 3B.

Comparison between the sample 2A and sample 3A of Comparative Example reveals that the transmittance in the sample 2A was increased by 12% compared to the transmittance in the sample 3A of Comparison Example. Comparison between the sample 2B and sample 3B of Comparative Example reveals that the transmittance in the sample 2B was increased by 1.5% compared to the transmittance in the sample 3B of Comparison Example. From these, the transmittance at the wavelength of 280 nm can be increased by forming the insulating anti-reflective layer 60.

Comparison between the samples 2A and 2B reveals that the transmittance in the sample 2A was increased by 55.7% compared to the transmittance in the sample 2B. Therefore, the transmittance at the wavelength of 280 nm can be increased by reducing the thickness of the p-side transparent electrode 40.

As shown in FIG. 4, at other wavelength bands, the sample 2A had a high transmittance at a wavelength band of 350 nm or less, and particularly, the sample 2A had a transmittance of roughly 50% or more at a wavelength band of 200 nm to 350 nm. Therefore, the light extraction efficiency of ultraviolet light can be increased by the structure of the sample 2A.

### 3. Effects

In the light emitting device 1 according to the present embodiment, the p-side electrode 50 is formed on one part on the p-type layer 23, and the insulating anti-reflective layer 60 is formed on other part on the p-type layer 23. The insulating anti-reflective layer 60 has a function to prevent reflection of ultraviolet light with an emission wavelength. Therefore, the light extraction efficiency of ultraviolet light can be increased in a region where the insulating anti-reflective layer 60 is disposed. Thus, the light extraction efficiency can be increased in the face-up type ultraviolet light emitting device.

The refractive index of the insulating anti-reflective layer 60 is preferably set between the refractive index of the p-side transparent electrode 40 and the refractive index of air. Thereby, the light extraction efficiency can be increased. Particularly, the insulating anti-reflective layer 60 preferably has a multilayer structure formed by depositing materials having different refractive indices. This allows that reflections are mutually weakened by the interference of light. As a result, the light extraction efficiency can be increased.

The insulating anti-reflective layer 60 preferably contains at least one selected from a group consisting of Hf oxide, Zr oxide, Si oxide, Al oxide, and Mg fluoride. Thereby, the insulating anti-reflective layer 60 can be formed so as to have a desired function.

In the light emitting device 1, by forming the p-side transparent electrode 40 on the p-type layer 23, the contact resistance with the p-type layer 23 can be reduced, thereby improving the emission efficiency. At this time, the p-side transparent electrode 40 is preferably formed thinner than the thickness of the insulating anti-reflective layer 60. Particularly, the thickness of the p-side transparent electrode 40 is 40 nm or less, preferably 20 nm or less. Thereby, the anti-reflection function can be improved in the insulating anti-reflective layer 60 while improving the transmittance of ultraviolet light in the p-side transparent electrode 40. As a result, the light extraction efficiency can be increased.

What is claimed is:

1. A face-up type ultraviolet light emitting device comprising:
an n-type layer made of n-type group III nitride semiconductor;
an active layer formed on the n-type layer and made of group III nitride semiconductor;
a p-type layer formed on the active layer and made of p-type group III nitride semiconductor;
a p-side electrode formed on one part on the p-type layer; and
an insulating anti-reflective layer formed on other part on the p-type layer, made of a material having insulating properties, and preventing reflection of ultraviolet light with an emission wavelength.

2. The light emitting device according to claim 1, further comprising:
a p-side transparent electrode formed on and in contact with the p-type layer, and transmitting ultraviolet light with an emission wavelength, wherein
the p-side electrode is formed on one part on the p-side transparent electrode, and
the insulating anti-reflective layer is formed on other part on the p-side transparent electrode.

3. The light emitting device according to claim 2, wherein the refractive index of the insulating anti-reflective layer is set between the refractive index of the p-side transparent electrode and the refractive index of air.

4. The light emitting device according to claim 1, wherein the insulating anti-reflective layer has a multilayer structure formed by depositing materials having different refractive indices.

5. The light emitting device according to claim 1, wherein the insulating anti-reflective layer contains at least one selected from a group consisting of Hf oxide, Zr oxide, Si oxide, Al oxide, and Mg fluoride.

6. The light emitting device according to claim 2, wherein the p-side transparent electrode is formed thinner than the thickness of the insulating anti-reflective layer.

7. The light emitting device according to claim 2, wherein the thickness of the p-side transparent electrode is 20 nm or less.

8. The light emitting device according to claim 7, wherein the thickness of the insulating anti-reflective layer is 1 nm to 300 nm.

9. The light emitting device according to claim 1, wherein the p-type layer is made of GaN or AlGaN.

10. An insulating anti-reflective layer used for a face-up type ultraviolet light emitting device, formed on a p-type layer, containing at least one selected from a group consisting of Hf oxide, Zr oxide, Si oxide, Al oxide, and Mg fluoride, and preventing reflectance of ultraviolet light with an emission wavelength.
